(19) United States
(12) Patent Application Publication
(10) Pub. No.: US 2011/0240602 A1
(43) Pub. Date: Oct. 6, 2011

(54) HIGH-VOLTAGE GAS CLUSTER ION BEAM (GCIB) PROCESSING SYSTEM

(75) Inventors: Robert K. Becker, Danvers, MA (US); Matthew C. Gwinn, Winchendon, MA (US); Kenneth P. Regan, Beverly, MA (US)

(73) Assignee: TEL Epion Inc., Billerica, MA (US)

(21) Appl. No.: 12/750,052

(22) Filed: Mar. 30, 2010

(51) Int. Cl. C23F 1/02; C23C 14/46

(52) U.S. Cl. 216/94; 156/345.39; 134/1

(57) ABSTRACT

The invention includes a high-voltage gas cluster ion beam (GCIB) processing system for treating a workpiece using a gas cluster ion beam. The high-voltage GCIB processing system includes a high-voltage (HV) source system that includes a high-voltage (HV) source chamber having a high-voltage (HV) nozzle subassembly, a nozzle element, and a high-voltage (HV) skimmer subassembly therein. The high-voltage gas cluster ion beam (GCIB) processing system includes a high-voltage (HV) power supply coupled to the HV nozzle subassembly and the HV skimmer subassembly. A high-voltage (HV) ionization chamber can be coupled to the HV source chamber and can include an ionizer coupled to the chamber wall by an isolation structure. In addition, a grounded GCIB processing chamber can be coupled to the HV ionization chamber by an isolation structure and can include a scanable workpiece holder.

### FIELD OF THE INVENTION

The invention relates generally to apparatus and methods for using a high-voltage (HV) gas cluster ion beam (GCIB) processing system to treat a workpiece.

### BACKGROUND INFORMATION

The use of a gas cluster ion beam (GCIB) for etching, cleaning, and smoothing surfaces is known in the art (see for example, U.S. Pat. No. 5,814,194, Deguchi, et al.). GCIBs have also been employed for assisting the deposition of films from vaporized carbonaceous materials (see for example, U.S. Pat. No. 6,416,820, Yamada, et al.). As the term is used herein, gas clusters are nano-sized aggregates of materials that are gaseous under conditions of standard temperature and pressure. Such clusters may be comprised of aggregates of from a few to several thousand molecules or more, loosely bound to form the clusters. The clusters can be ionized by electron bombardment or other means, permitting them to be formed into directed beams of controllable energy. Such ions each typically carry positive charges. The larger sized clusters are often the most useful because of their ability to carry substantial energy per cluster ion, while yet having only modest energy per molecule. The clusters disintegrate on impact, with each individual molecule carrying only a small fraction of the total cluster energy. Consequently, the impact effects of large clusters are substantial, but are limited to a very shallow surface region. This makes ion clusters effective for a variety of surface modification processes, without the tendency to produce deeper subsurface damage characteristic of conventional ion beam processing.

Means for creation and acceleration of such GCIBs are described in the reference (U.S. Pat. No. 5,814,194) previously cited, the teachings of which are incorporated herein by reference. Presently available ion cluster sources produce clusters ions having a wide distribution of sizes, N, up to N of several thousand (where N=the number of molecules in each cluster—in the case of monatomic gases like argon, an atom of the monatomic gas will be referred to as either an atom or a molecule and an ionized atom of such a monatomic gas will be referred to as either an ionized atom, or a molecular ion, or simply a monomer ion—throughout this discussion).

Many useful surface-processing effects can be achieved by bombarding surfaces with GCIBs. These processing effects include, but are not necessarily limited to, smoothing, etching, film growth, and infusion of materials into surfaces. In many cases, it is found that in order to achieve industrially practical throughputs in such processes, GCIB currents of hundreds or perhaps thousands of microamps are required. Experimental GCIB beam currents have been reported in the range of several hundreds or a few thousands of microamperes typically in the form of short duration transient beam bursts. But, for industrial productivity and high quality surface processing results, GCIB processing equipment for etching, smoothing, cleaning, infusing, or film formation must produce steady, long-term-stable beams so that GCIB processing of a workpiece surface can proceed for minutes or hours without interruption or beam current transients. GCIB processing equipment possessing such long-term stability has been heretofore limited to beam currents of about a few hundreds of microamperes. Attempts to form higher beam currents have heretofore generally resulted in beams without long-term stability and having frequent beam transients (commonly called “glitches”) resulting from arcing or other transient effects in the beamlines. Such transients can arise in a variety of ways, but their effect is to produce non-uniform processing of the workpieces or, in the case of severe arcing, even physical damage to, or transient misbehavior of control systems in the GCIB processing systems.

In some earlier GCIB systems, a voltage rise across the gas jet from the nozzle to the ion source (or skimmer to ion source, or differential pumping aperture to the ion source) could create a discharge in the gas cluster jet, effectively destroying the jet. A skimmer gate was used in some GCIB designs to lessen the problem, but the skimmer gate still has limitations (path length required and gas flux) in its ability to prevent the discharge. In addition, some of the ion source chamber designs can exhibit a discharge problem from the ion source to the grounded ion source chamber walls. The discharge problem limits the maximum pressure in the region and leads to “glitching”.

The present invention solves the discharge problems without using a skimmer gate and allows the GCIB system to operate at higher voltages.

### SUMMARY OF INVENTION

A high-voltage gas cluster ion beam (GCIB) processing system is provided in one embodiment for treating a workpiece using a gas cluster ion beam (GCIB). The system comprises a high-voltage (HV) source system including a high-voltage (HV) source chamber that has a high-voltage (HV) nozzle subassembly and a high-voltage (HV) skimmer subassembly therein, and a high-voltage (HV) ionization system including a high-voltage (HV) ionization chamber coupled to the HV source chamber. A nozzle element is coupled to the HV nozzle subassembly and has a nozzle output configured to create an internal cluster beam, and the HV skimmer subassembly has an input aperture and an output aperture configured to receive the internal cluster beam and create a neutral cluster beam in the HV ionization chamber. A multi-output high-voltage (HV) power supply is coupled to the HV nozzle subassembly and to the HV skimmer subassembly using one or more first high-voltage (HV) feed-through elements (ft₁), and an ionization subsystem is configured within the HV ionization chamber using one or more first high-voltage (HV) isolation structures and is coupled to the multi-output HV power supply using one or more second high-voltage (HV) feed-through elements (ft₂). The ionization subsystem is configured to receive and ionize clusters in the neutral cluster beam to form an ionized GCIB. A scanable workpiece holder is coupled to a grounded GCIB processing chamber at a ground potential and the grounded GCIB processing chamber is coupled to the HV ionization chamber using one or more second high-voltage (HV) isolation structures. The scanable workpiece holder is configured for establishing relative scanning motion between the workpiece and the ionized GCIB so that ionized clusters of the ionized GCIB impinge a surface of the workpiece. In addition, a controller is coupled to the multi-output HV power supply and to the scanable workpiece holder using a signal bus.

A method for treating a workpiece using a high-voltage GCIB processing system is provided in another embodiment. The method comprises creating an internal cluster beam in an HV source chamber using a nozzle element in an HV nozzle subassembly, wherein the nozzle element has a nozzle output configured to create the internal cluster beam, and creating a neutral cluster beam using an HV skimmer subassembly having an input aperture and an output aperture configured to receive the internal cluster beam and create the neutral cluster beam in an HV ionization chamber coupled to the HV source chamber. A nozzle voltage (V_{Noz}) is provided to the HV nozzle subassembly using an output from a multi-output HV power supply and one or more first HV feed-through elements (ft₁), and a skimmer voltage (V_{Skm}) is provided to the HV skimmer subassembly using the multi-output HV power supply and the one or more first HV feed-through elements (ft₁). The method further includes forming an ionized GCIB using an ionizer in the HV ionization chamber wherein the ionizer is coupled to at least one wall of the HV ionization chamber using one or more first HV isolation structures and is coupled to the multi-output HV power supply using one or more second HV feed-through elements (ft₂), the ionizer being configured to receive and ionize clusters in the neutral cluster beam to form the ionized GCIB. The workpiece is then scanned through the ionized GCIB using a scanable workpiece holder coupled to a grounded GCIB processing chamber at a ground potential, the grounded GCIB processing chamber being coupled to the HV ionization chamber using one or more second HV isolation structures. The scanable workpiece holder is configured for establishing relative scanning motion between the workpiece and the ionized GCIB so that ionized clusters of the ionized GCIB impinge a surface of the workpiece.

### BRIEF DESCRIPTION OF THE DRAWINGS

The present invention is illustrated by way of example and not as a limitation in the figures of the accompanying drawings, in which:

FIG. 1 shows a typical configuration for a Gas Cluster Ion Beam (GCIB) processing system of a form known in prior art;

FIG. 2 shows an exemplary configuration for a high-voltage GCIB processing system in accordance with embodiments of the invention; and

FIG. 3 shows an exemplary flow diagram of a method for treating a workpiece using a high-voltage GCIB processing system in accordance with embodiments of the invention.

### DETAILED DESCRIPTION

In efforts to achieve stable high current GCIBs for workpiece processing in a GCIB processing system, developments in GCIB ionization sources, management of beam space charge, and management of workpiece charging have all been important areas of development. U.S. Pat. No. 6,629,508 to Dykstra; U.S. Pat. No. 6,646,277 to Mack et al.; and co-pending U.S. patent application Ser. No. 10/667,006, the contents of all of which are incorporated herein by reference as though set out at length herein, each describe advances in several of these areas that have resulted in the ability to produce GCIB beams of at least several hundreds of microamperes to one or more milliamperes of beam current. These beams, however, can exhibit, in some cases, instabilities that may limit their optimal use in industrial applications. In general, the generation of higher GCIB beam currents results in the introduction of greater amounts of gas into the beamline. Inherently, a GCIB transports gas. Accordingly, for a beam current of only 400 microamperes and an N/q ratio of 5000, the beam conducts a substantial gas flow of about 27 sccm. In a typical GCIB processing tool, the ionizer and the workpiece being processed are each typically contained in separate chambers. This provides for better control of system pressures. However, even with excellent vacuum system design and differential isolation of various regions of the apparatus, a major area of difficulty with beams carrying large amounts of gas is that pressures may increase throughout the beamline. The entire gas load of the beam is released when the GCIB strikes the target region, and some of this gas influences pressures throughout the GCIB processing system's vacuum chambers. Because high voltages are often used in the formation and acceleration of GCIBs, increased beamline pressures can result in arcing, discharges, and other beam instabilities. As beam currents are increased, gas transport by the beam increases and pressures throughout the beamline become more difficult to manage. Because of the unique ability of a GCIB, compared to a conventional ion beam, to transport and release large amounts of gas throughout the beamline, pressure related beam instabilities and electrical discharges are much more of a problem for high current GCIBs than for conventional ion beams. In a typical GCIB ion source, neutral gas clusters in a beam are ionized by electron bombardment. The ionizer region is generally a relatively poor vacuum region and is typically at a high electrical potential relative to surrounding structures.

In some embodiments of the high-voltage GCIB processing system, the nozzle (and skimmer and differential pumping aperture) and ion source can be operated at substantially the same potential. When there is no potential difference, there is no acceleration of charges from the ion source to the nozzle, and there is no discharge in the gas jet. It is believed that by eliminating the tendency for these charges to accelerate along this path, the invention provides a more effective solution for eliminating the discharge problem than the skimmer gate provides.

It is further believed that the invention provides an increase of gas flux and a reduction in length of the beamline because the ion source is at the same potential as the gas delivery/skimmer components. In addition, the increase in allowable gas flux can also create a wider operating space for generating optimum cluster distributions.

It is also believed that when the ion source chamber is floated to high voltage there is no, or minimal, voltage drop from the ion source to the vacuum chamber walls eliminating the tendency to discharge across this gap. In addition, it is believed that the inventive design can allow a smaller chamber and eliminate the need for some of the charge containment elements of the ion source, and this could provide lower particulate and metallic contamination.

Because of the above features, in combination, higher voltage operation of the ion source relative to ground may be allowed.

The present invention uses a combination of high-voltage subassemblies, high-voltage subsystems, isolation structures, and shielding techniques to reduce the frequency of transients occurring in a high-voltage GCIB processing system.

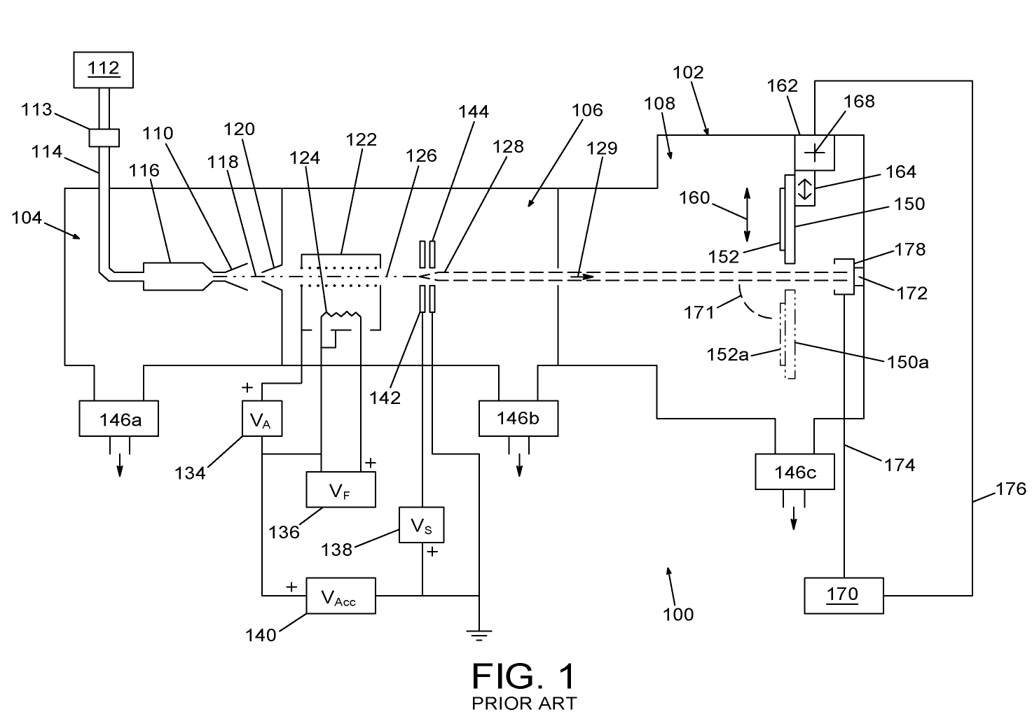

FIG. 1 shows a configuration for a GCIB processing apparatus 100 of a form known in prior art, and which may be described as follows: a vacuum vessel 102 is divided into three communicating chambers, a source chamber 104, an ionization/acceleration chamber 106, and a processing chamber 108. The three chambers are evacuated to suitable operating pressures by vacuum pumping systems 146a, 146b, and 146c, respectively. A condensable gas (for example, argon (Ar), carbon dioxide (CO₂), oxygen (O₂), or nitrogen (N₂)) is admitted under pressure from a condensable gas source 112 through gas metering valve 113 and gas feed tube 114 into stagnation chamber 116 and is ejected into the substantially lower pressure vacuum through a properly shaped nozzle 110. A supersonic gas jet 118 can be created. Cooling, which results from the expansion in the jet, causes a portion of the gas jet 118 to condense into clusters, each consisting of from several to several thousand weakly bound atoms or molecules. A gas skimmer aperture 120 partially separates the gas molecules that have not condensed into a cluster jet from the cluster jet so as to minimize pressure in the downstream regions where such higher pressures would be detrimental (e.g., ionizer 122, suppressor electrode 142, and processing chamber 108). Suitable condensable source gases 112 include, but are not limited to argon, nitrogen, carbon dioxide, oxygen, NF₃, and other gases and/or gas mixtures.

After the supersonic gas jet 118 containing gas clusters has been formed, the clusters are ionized in an ionizer 122. The ionizer 122 is typically an electron impact ionizer that produces thermo-electrons from one or more incandescent filaments 124, accelerates and directs the electrons, causing them to collide with the gas clusters in the gas jet 118 where the jet passes through the ionizer 122. The electron impacts with clusters eject electrons from the clusters, causing a portion the clusters to become positively ionized. Some clusters may have more than one electron ejected and may become multiply ionized. Suppressor electrode 142, and grounded electrode 144 extract the cluster ions from the ionizer exit aperture 126, accelerate them to a desired energy (typically with acceleration potentials of from several hundred V to several tens of kV), and focuses them to form a GCIB 128. The axis 129 of the supersonic gas jet 118 containing gas clusters is substantially the same as the axis of the GCIB 128. Filament power supply 136 provides filament voltage V_{F} to heat the ionizer filament 124. Anode power supply 134 provides anode voltage V_{A} to accelerate thermo-electrons emitted from filament 124 to cause the thermo-electrons to irradiate the cluster-containing gas jet 118 to produce cluster ions. Suppression power supply 138 provides suppression voltage V_{S} to bias suppressor electrode 142. Accelerator power supply 140 provides acceleration voltage (V_{Acc}) to bias the ionizer 122 with respect to suppressor electrode 142 and grounded electrode 144 so that a total GCIB acceleration potential can be equal to about (V_{Acc}). Suppressor electrode 142 serves to extract ions from the ionizer exit aperture 126 of ionizer 122, to prevent undesired electrons from entering the ionizer 122 from downstream, and to form a focused GCIB 128.

A workpiece 152, which may be a semiconductor wafer or other workpiece to be processed by GCIB processing, is held on a workpiece holder 150, which can be disposed in the path of the GCIB 128. Since most applications contemplate the processing of large workpieces with spatially uniform results, a scanning system is desirable to uniformly scan a large-area workpiece 152 through the stationary GCIB 128 to produce spatially homogeneous workpiece processing results.

An X-scan actuator 162 provides linear motion of the workpiece holder 150 in the direction of X-scan motion 168 (into and out of the plane of the paper). A Y-scan actuator 164 provides linear motion of the workpiece holder 150 in the direction of Y-scan motion 160, which is typically orthogonal to the X-scan motion 168. The combination of X-scanning and Y-scanning motions moves the workpiece 152, held by the workpiece holder 150 in a raster-like scanning motion through GCIB 128 to cause a uniform (or otherwise programmed) irradiation of a surface of the workpiece 152 by the GCIB 128 for processing of the workpiece 152. The workpiece holder 150 disposes the workpiece 152 at an angle with respect to the axis of the GCIB 128 so that the GCIB 128 has an angle of beam incidence 171 with respect to a workpiece 152 surface. The angle of beam incidence 171 may be 90 degrees or some other angle, but is typically 90 degrees or near 90 degrees. During Y-scanning, the workpiece 152 and the workpiece holder 150 move from the position shown to the alternate position “A” indicated by the designators 152A and 150A respectively. Notice that in moving between the two positions, the workpiece 152 is scanned through the GCIB 128 and in both extreme positions, is moved completely out of the path of the GCIB 128 (over-scanned). Though not shown explicitly in FIG. 1, similar scanning and over-scan is performed in the (typically) orthogonal X-scan motion 168 direction (in and out of the plane of the paper).

A beam current sensor 178 is disposed beyond the workpiece holder 150 in the path of the GCIB 128 to intercept a sample of the GCIB 128 when the workpiece holder 150 is scanned out of the path of the GCIB 128. The beam current sensor 178 is typically a faraday cup or the like, closed except for a beam-entry opening, and is typically affixed to the wall of the vacuum vessel 102 with an electrically insulating mount 172.

A controller 170, which may be a microcomputer based controller, connects to the X-scan actuator 162 and the Y-scan actuator 164 through electrical cable 176 and controls the X-scan actuator 162 and the Y-scan actuator 164 so as to place the workpiece 152 into or out of the GCIB 128 and to scan the workpiece 152 uniformly relative to the GCIB 128 to achieve desired processing of the workpiece 152 by the GCIB 128. Controller 170 receives the sampled beam current collected by the beam current sensor 178 by way of lead 174 and thereby monitors the GCIB and controls the GCIB dose received by the workpiece 152 by removing the workpiece 152 from the GCIB 128 when a predetermined desired dose has been delivered.

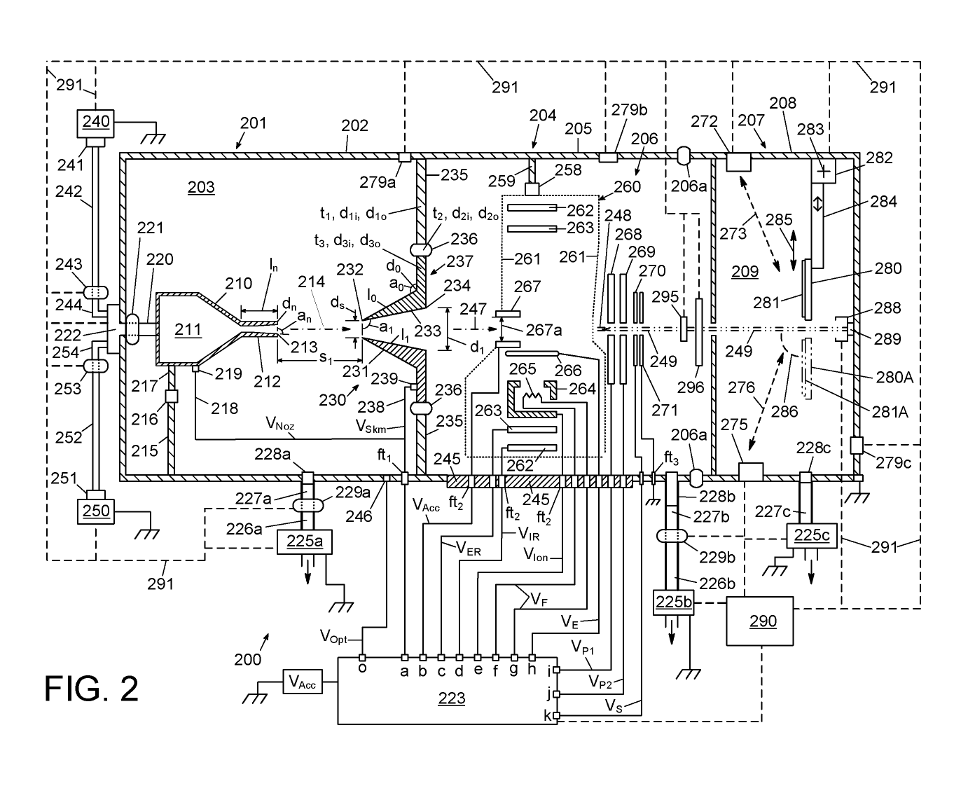

FIG. 2 shows an exemplary configuration for a high-voltage (HV) GCIB processing system in accordance with embodiments of the invention. The high-voltage (HV) GCIB processing system 200 comprises a high-voltage (HV) source system 201, a high-voltage (HV) ionization system 204, and an isolated GCIB processing system 207. The HV source system 201 can include a high-voltage (HV) source chamber 202 having a first interior space 203, and the HV ionization system 204 can include a high-voltage (HV) ionization chamber 205 having a second interior space 206, with the HV source chamber 202 being coupled to the HV ionization chamber 205. In accordance with an embodiment of the invention, the HV ionization chamber 205 includes an ionization subsystem 260 configured therein using one or more first high-voltage (HV) isolation structures 258, as will be described in more detail below. The isolated GCIB processing system 207 can include a grounded GCIB processing chamber 208 having an isolated GCIB processing space 209. In accordance with an embodiment of the invention, the isolated GCIB processing system 207 can be isolated from the HV ionization system 204 using one or more second isolation structures 206a that can be configured between the HV ionization chamber 205 and the grounded GCIB processing chamber 208, as will be described in more detail below.

In some embodiments, the HV source system 201 can include a high-voltage (HV) nozzle subassembly 210 that can be positioned in the first interior space 203 of the HV source chamber 202 when the HV GCIB processing system 200 is constructed. The HV nozzle subassembly 210 can be cylindrically shaped and can include a process space 211 that is cylindrically shaped.

A nozzle element 212 can be coupled to the HV nozzle subassembly 210 and can be coupled to the process space 211 in the HV nozzle subassembly 210. The nozzle element 212 can be used to create an internal cluster beam 214 in the first interior space 203 in the HV source chamber 202. The nozzle element 212 can have a nozzle length (lₙ), a nozzle angle (aₙ), and a nozzle output aperture 213 having a diameter (dₙ). The nozzle length (lₙ) can vary from about 5 mm to about 20 mm; the nozzle angle (aₙ) can vary from about 92 degrees to about 135 degrees; and the nozzle diameter (dₙ) is determined by (lₙ) and (aₙ). The nozzle length (lₙ), the nozzle angle (aₙ), and the nozzle diameter (dₙ) can be determined by the process chemistry, the molecule size, the flow rates, the chamber pressures, and the required diameter for the internal cluster beam 214.

In some configurations, the HV nozzle subassembly 210 can be coupled to one or more walls in the HV source chamber 202 using one or more first mounting elements 215, one or more third high-voltage (HV) isolation structures 216, and one or more second mounting elements 217. Alternatively, the HV nozzle subassembly 210 may be mounted differently. In one embodiment, the HV nozzle subassembly 210 can be cylindrically shaped with an outside diameter that can vary from about 20 mm to about 300 mm; the first mounting elements 215 can have a square shape with a width that can vary from about 5 mm to about 20 mm and a length that can vary from about 5 mm to about 100 mm; the third HV isolation structures 216 can have a square shape with a width that can vary from about 5 mm to about 100 mm and a length that can vary from about 5 mm to about 100 mm; and the second mounting elements 217 can have a square shape with a width that can vary from about 5 mm to about 20 mm and a length that can vary from about 5 mm to about 100 mm.

In some embodiments, a multi-output high voltage (HV) power supply 223 can be referenced to a ground potential via the acceleration voltage (V_{Acc}) power supply. The multi-output HV power supply 223 can include one or more high-voltage modules that can be configured in a High Voltage pod.

When the HV nozzle subassembly 210 is isolated from the walls of the HV source chamber by the third HV isolation structures 216, the HV nozzle subassembly 210 can be operated using a high DC voltage. The HV nozzle subassembly 210 can be coupled to one or more first outputs (a) of a multi-output high-voltage (HV) power supply 223 using one or more first HV supply lines 218, one or more first terminals 219, and one or more first feed-through elements (ft₁). The multi-output HV power supply 223 can provide a nozzle voltage (V_{Noz}) to bias the HV nozzle subassembly 210 and the nozzle element 212 when forming an internal cluster beam 214. Alternatively, nozzle voltage (V_{Noz}) may be provided by a different power supply. In some examples, the nozzle voltage (V_{Noz}) can vary from about −10000 volts to about +10000 volts. In other examples, the nozzle voltage (V_{Noz}) can vary from about −100000 volts to about +100000 volts.

In some alternate embodiments, one or more terminals 246 may be coupled to one or more of the walls of the HV source chamber 202, and one or more of the terminals 246 may be coupled to one or more optional outputs (o) of the multi-output HV power supply 223. The multi-output HV power supply 223 can provide an optional voltage (V_{Opt}) to bias the HV source chamber 202 and/or the HV ionization chamber 205. Alternatively, optional voltage (V_{Opt}) may be provided by a different power supply. In some examples, the optional voltage (V_{Opt}) can vary from about −10000 volts to about +10000 volts.

In some embodiments, one or more gas feed elements 220 can be coupled to the HV nozzle subassembly 210, and one or more of the gas feed elements 220 can provide one or more process gases to process space 211 and can be used to control the pressure within the process space 211. In other embodiments, a number of HV nozzle subassemblies 210 can be used.

In addition, a mixing subassembly 222 can be coupled to one or more of the gas feed elements 220 using one or more isolating feed elements 221. Alternatively, the gas feed elements 220 may have high-voltage isolation properties. The mixing subassembly 222 can provide one or more process gases to the gas feed elements 220 and can be used to control the number and amount of process gases provided to the HV nozzle subassembly 210. The controller 290 can be connected to the mixing subassembly 222 using signal bus 291, and the controller 290 can be used to monitor and/or control the mixing subassembly 222. For example, the controller 290 can be used to control the process gas chemistry, the process gas flow rate, the process gas pressure, the mixing amounts, the mixing rates, and/or the processing times. In addition, the gas feed elements 220 and/or the mixing subassembly 222 can include flow control devices, filters, and valves as required.

Some HV GCIB processing systems 200 can include a first gas supply subsystem 240, and the first gas supply subsystem 240 can be connected to at least ground potential. Alternatively, the first gas supply subsystem 240 may be connected to one or more first high-voltage (HV) power supplies (not shown).

The first gas supply subsystem 240 can be coupled to the mixing subassembly 222 using one or more first flow control elements 241, one or more first external gas supply lines 242, one or more first high-voltage (HV) isolator elements 243, and one or more second gas supply lines 244. The first gas supply subsystem 240 can be isolated from the HV source system 201 using the one or more first HV isolator elements 243. The first HV isolator element 243 can comprise one or more high voltage components. For example, one or more high voltage bushings may be used. Alternatively, the first HV isolator elements 243 may not be required or may be connected differently. In addition, the first gas supply system 240 can be configured to more safely operate in the HV GCIB processing system 200, as will be discussed further below.

In addition, the first flow control elements 241, the first external gas supply lines 242, the first HV isolator elements 243, and/or the second gas supply lines 244 can include flow control devices, filters, and valves as required. The controller 290 can be connected to the first gas supply subsystem 240 and the first HV isolator element 243 using signal bus 291, and the controller 290 can be used to monitor and/or control the first gas supply subsystem 240 and the first HV isolator element 243. For example, the first flow rates for the first gas supply subsystem 240 can vary from about 10 sccm to about 3000 sccm.

In addition, some HV GCIB processing systems 200 can also include a second gas supply subsystem 250, and the second gas supply subsystem 250 can be connected to at least ground potential. Alternatively, the second gas supply subsystem 250 may be connected to one or more high-voltage (HV) power supplies (not shown).

The second gas supply subsystem 250 can be coupled to the mixing subassembly 222 using one or more second flow control elements 251, one or more second external gas supply lines 252, one or more second high-voltage (HV) isolator elements 253, and one or more additional second gas supply lines 254. The second gas supply subsystem 250 can be isolated from the HV source system 201 using the one or more second HV isolator elements 253. The second HV isolator element 253 can comprise a one or more high voltage components. For example, one or more high voltage bushings may be used. Alternatively, the second HV isolator elements 253 may not be required or may be connected differently. In addition, the second gas supply subsystem 250 can be configured to more safely operate in the HV GCIB processing system 200, as will be discussed further below.

In addition, the second flow control elements 251, the second external gas supply lines 252, the second HV isolator elements 253, and/or the additional second gas supply lines 254 can include flow control devices, filters, and valves as required. The controller 290 can be connected to the second gas supply subsystem 250 and the second HV isolator elements 253 using signal bus 291, and the controller 290 can be used to monitor and/or control the second gas supply subsystem 250 and the second HV isolator element 253. For example, the second flow rates for the second gas supply subsystem 250 can vary from about 10 sccm to about 3000 sccm.

In some embodiments, one or more of the first gas system elements (240, 241, 242, 243 and 244) can be enclosed within a vented pod (not shown), and this can improve gas delivery safety. For example, if customers required the gas to be provided by an in house bulk system, this would not create a problem as the gas could be delivered across the high voltage gap through custom designed metal to glass (or other suitable insulating material) feed through. As the gas would be at high pressure, there is no chance of discharge occurring within the feed through. Likewise, in some embodiments, one or more of the second gas system elements (250, 251, 252, 253 and 254) can be enclosed within a vented pod for improved safety.

In some examples, the controller 290 can be connected to the first HV isolator elements 243 and the second HV isolator elements 253 using signal bus 291, and the controller 290 can be used to monitor and/or control the first HV isolator elements 243 and the second HV isolator elements 253. For example, monitoring may be performed to ensure a safe operating environment. Alternatively, the controller 290 may not be connected to the first HV isolator elements 243 and the second HV isolator elements 253.

In some embodiments, the HV source system 201 can include a high-voltage (HV) skimmer subassembly 230 that can be positioned in the first interior space 203 of the HV source chamber 202 when the high-voltage GCIB processing system 200 is constructed. The HV skimmer subassembly 230 can be cylindrically shaped. For example, the HV skimmer subassembly 230 may be positioned to separate the first interior space 203 of the HV source chamber 202 from the second interior space 206 of the HV ionization chamber 205 when the high-voltage GCIB processing system 200 is constructed. The HV skimmer subassembly 230 can include a coupling portion 237 that can be coupled to one or more walls in the HV source chamber 202 using one or more first mounting structures 235, and one or more fourth high-voltage (HV) isolation structures 236. As shown, the fourth HV isolation structures 236 isolate the HV skimmer subassembly 230 from the walls of the HV source chamber 200 and the walls of the HV ionization chamber 205. Alternatively, the HV skimmer subassembly 230 may be mounted differently. In one embodiment, the first mounting structures 235 can have a ring shape, and can have a first thickness (t₁) that can vary from about 2 mm to about 10 mm, a first inside diameter (d₁ᵢ) that can vary from about 100 mm to about 300 mm, and a first outside diameter (d₁ₒ) that can vary from about 200 mm to about 1000 mm. Alternatively, the first mounting structures 235 may be configured differently. In addition, the fourth HV isolation structures 236 can have an annular ring shape, and can have a second thickness (t₂) that can vary from about 5 mm to about 20 mm, a second inside diameter (d₂ᵢ) that can vary from about 50 mm to about 300 mm, and a second outside diameter (d₂ₒ) that can vary from about 300 mm to about 1000 mm. Alternatively, the fourth HV isolation structures 236 may be configured differently. The coupling portion 237 can have an annular ring shape, and can have a third thickness (t₃) that can vary from about 5 mm to about 20 mm, a third inside diameter (d₃ᵢ) that can vary from about 10 mm to about 30 mm, and a third outside diameter (d₃ₒ) that can vary from about 20 mm to about 50 mm.

When the HV skimmer subassembly 230 is isolated from the walls of the HV source chamber 202 and/or the walls of the HV ionization chamber 205 by the fourth HV isolation structures 236, the HV skimmer subassembly 230 can be operated using a high DC voltage. Alternately, an AC voltage may be used. The HV skimmer subassembly 230 can be coupled to one or more of the first outputs (a) of the multi-output HV power supply 223 using one or more second supply lines 238, one or more second terminals 239, and one or more of the first feed-through elements (ft₁). Alternatively, a separate output may be used from the multi-output HV power supply 223 or a separate power supply may be used. The multi-output HV power supply 223 can provide a skimmer voltage (V_{Skm}) to bias the HV skimmer subassembly 230 when forming a high-voltage (HV) neutral cluster beam 247. For example, the skimmer voltage (V_{Skm}) can vary from about −10000 volts to about +10000 volts. Alternatively, the skimmer voltage (V_{Skm}) may vary from about −100000 volts to about +100000 volts. In some examples, the skimmer voltage (V_{Skm}) can be about equal to the nozzle voltage (V_{Noz}). In other examples, the skimmer voltage (V_{Skm}) can be different from the nozzle voltage (V_{Noz}). The controller 290 can be coupled to the multi-output HV power supply 223 and can be used to determine the value for the skimmer voltage (V_{Skm}). Alternatively, an internal controller (not shown) may be used.

The HV skimmer subassembly 230 can include an inner skimmer element 231 that has a conical configuration. The inner skimmer element 231 can include a skimmer input aperture 232. The skimmer input aperture 232 can have an inner diameter (dₛ) that can vary from about 0.1 mm to about 10 mm. A length (l₀), an angle (a₀), and an outer diameter (d₀) can be associated with the inner skimmer element 231. The length (l₀) can vary from about 20 mm to about 40 mm, and the angle (a₀) can vary from about 100 degrees to about 175 degrees. The inner diameter (dₛ), the length (l₀) and the angle (a₀) can be dependent upon the desired width for the neutral cluster beam 247, the gas cluster size, and the process chemistry (gases) that the skimmer subassembly 230 is designed to use. Alternatively, the inner skimmer element 231 may be configured differently.

The skimmer subassembly 230 can include an outer skimmer element 233 that has a conical configuration. The outer skimmer element 233 also includes skimmer input aperture 232, as defined above, and a circular output aperture 234. The circular output aperture 234 can have a first diameter (d₁) that can vary from about 5 mm to about 10 mm. A first length (l₁) and a first angle (a₁) can be associated with the outer skimmer element 233. The first length (l₁) can vary from about 20 mm to about 40 mm, and the first angle (a₁) can vary from about 100 degrees to about 175 degrees. The first diameter (d₁), the first length (l₁) and the first angle (a₁) can be dependent upon the desired width for the neutral cluster beam 247, the gas cluster size, and the process chemistry (gases) that the skimmer subassembly 230 is designed to use. Alternatively, the skimmer subassembly 230 and/or the outer skimmer element 233 may be configured differently.

The nozzle output aperture 213 can be separated from the skimmer input aperture 232 by a separation distance (s₁) that can vary from about 10 mm to about 50 mm. Alternatively, other separation distances (s₁) may be used. The correct separation distance (s₁) can be established when the high-voltage GCIB processing system 200 is aligned, tested, and/or operated. When the separation distance (s₁) is not correct, the gas feed elements 220, the HV nozzle subassembly 210, the nozzle element 212, or the HV skimmer subassembly 230, or any combination thereof can be repositioned or re-manufactured. The separation distance (s₁) can be dependent upon the process chemistry (gases) that the high-voltage GCIB processing system 200 is designed to use.

Before the HV GCIB processing system 200 is used, the HV skimmer subassembly 230 can be aligned with the nozzle element 212. For example, the nozzle output aperture 213 and the internal cluster beam 214 established thereby can be aligned with and directed towards the skimmer input aperture 232 in the HV skimmer subassembly 230. In some embodiments, the nozzle element 212 can be cleaned and/or tested before being used. When the internal cluster beam 214 is aligned correctly, the HV nozzle subassembly 210 and the HV skimmer subassembly 230 can be rigidly coupled to one or more of the interior walls of the HV source chamber 202 to maintain the correct alignment.

In some embodiments, the HV GCIB processing system 200 can include a first isolated vacuum pumping subsystem 225a, and one or more first output control elements 228a coupled into the HV source chamber 202. For example, first output control elements 228a can be used to measure exhaust rates, exhaust chemistry, chamber pressures, chamber temperatures, and/or chamber chemistries. Alternatively, a first output control element 228a may not be required. When a first output control element 228a is used, it can be coupled to the first isolated vacuum pumping system 225a using one or more first external exhaust elements (226a, and 227a) and one or more first high-voltage (HV) exhaust isolators 229a. For example, the first external exhaust elements (226a, and 227a) and/or the first HV exhaust isolators 229a can have high-voltage isolation properties.

In addition, a first chamber-monitoring device 279a can be coupled to the HV source chamber 202, and can be used to measure chamber pressures, chamber temperatures, and chamber chemistries. Alternatively, the first HV exhaust isolator 229a and/or the first chamber-monitoring device 279a may be configured differently or may not be required.

Furthermore, the controller 290 can be connected to the first isolated vacuum pumping system 225a and the first chamber-monitoring device 279a using signal bus 291, and the controller 290 can be used to monitor and/or control the first isolated vacuum pumping system 225a and the first chamber-monitoring device 279a. In other exemplary configurations, the controller 290 can be connected to the first HV exhaust isolators 229a using signal bus 291, and the controller 290 can be used to monitor and/or control the first HV exhaust isolators 229a. Alternatively, the controller 290 may not be connected to the first HV exhaust isolators 229a.

The HV GCIB processing system 200 can include a second isolated vacuum pumping subsystem 225b, and one or more second output control elements 228b coupled into the HV ionization chamber 205. For example, a second output control element 228b can be used to measure exhaust rates, exhaust chemistry, chamber pressures, chamber temperatures, and/or chamber chemistries. Alternatively, a second output control element 228b may not be required. When a second output control element 228b is used, it can be coupled to the second isolated vacuum pumping system 225b using one or more second external exhaust elements (226b, and 227b) and one or more second high-voltage (HV) exhaust isolators 229b. For example, the second external exhaust elements (226b, and 227b) and/or the second HV exhaust isolators 229b can have high-voltage isolation properties.

In some examples, a second chamber-monitoring device 279b can be coupled to the HV ionization chamber 205 and can be used to measure chamber pressures, chamber temperatures, and/or chamber chemistries in the HV ionization chamber 205. Alternatively, the second HV exhaust isolator 229b and/or the second chamber-monitoring device 279b may be configured differently or may not be required.

Furthermore, the controller 290 can be connected to the second isolated vacuum pumping system 225b and the second chamber-monitoring device 279b using signal bus 291, and the controller 290 can be used to monitor and/or control the second isolated vacuum pumping system 225b and the second chamber-monitoring device 279b. In other exemplary configurations, the controller 290 can be connected to the second HV exhaust isolators 229b using signal bus 291, and the controller 290 can be used to monitor and/or control the second HV exhaust isolators 229b. Alternatively, the controller 290 may not be connected to the second HV exhaust isolators 229b.

The HV GCIB processing system 200 can include a third vacuum pumping subsystem 225c, and one or more third output control elements 228c coupled into the grounded GCIB processing chamber 208. For example, a third output control element 228c can be used to measure exhaust rates, exhaust chemistry, chamber pressures, chamber temperatures, and/or chamber chemistries. One or more of the third output control elements 228c can be coupled to the third vacuum pumping system 225c using one or more third external exhaust elements 227c. In some examples, a third external exhaust element 227c can have high-voltage isolation properties. In addition, a third chamber-monitoring device 279c can be coupled to the grounded GCIB processing chamber 208 and can be used to measure chamber pressures, chamber temperatures, and/or chamber chemistries in the grounded GCIB processing chamber 208. Alternatively, the third chamber-monitoring device 279c may be configured differently or may not be required.

Furthermore, the controller 290 can be connected to the third vacuum pumping system 225c and the third chamber-monitoring device 279c using signal bus 291, and the controller 290 can be used to monitor and/or control the third vacuum pumping system 225c and the third chamber-monitoring device 279c.

The HV source chamber 202 and the HV ionization chamber 205 can be evacuated to suitable testing and/or operating pressures by isolated vacuum pumping systems (225a and 225b) when the HV GCIB processing system 200 is being aligned, tested, and/or used. The grounded GCIB processing chamber 208 can be evacuated to suitable testing and/or operating pressures by the third vacuum pumping system 225c when the HV GCIB processing system 200 is being aligned, tested, and/or used. One or more of the vacuum pumping systems (225a, 225b, and 225c) can include turbo-molecular vacuum pumps (TMP) capable of pumping speeds up to about 5000 liters per second (and greater) and a gate valve for throttling the chamber pressure. In conventional vacuum processing devices, a 1000 to 2000 liter per second TMP can be employed. TMPs are useful for low pressure processing, typically less than about 50 mTorr. In addition, the chamber-monitoring devices (279a, 279b, and 279c) can be vacuum gauges.

In some embodiments, the first isolated vacuum pumping system 225a can be coupled to a ground potential. Alternatively, the TMPs and/or other components of the first isolated vacuum pumping system 225a can be configured at a different potential. In addition, the second isolated vacuum pumping system 225b can be coupled a ground potential. Alternatively, the TMPs and/or other components of the second isolated vacuum pumping system 225b can be configured at a different potential. Furthermore, the third vacuum pumping system 225c can be coupled a ground potential. Alternatively, the TMPs and/or other components of the third vacuum pumping system 225c can be configured at a different potential.

A first gas composition stored in the first gas supply subsystem 240 and/or a second gas composition stored in the second gas supply subsystem 250 can be used when the HV GCIB processing system 200 is being aligned, tested, and/or used. In some examples, the HV GCIB processing system 200 can be configured to use a first gas composition, and the first gas composition can include a condensable inert gas that can include a noble gas, i.e., He, Ne, Ar, Kr, Xe, or Rn. In other examples, the HV GCIB processing system 200 can be configured to use a second gas composition that can comprise a film forming gas composition, an etching gas composition, a cleaning gas composition, a smoothing gas composition, etc. Furthermore, the first gas supply subsystem 240 and the second gas supply subsystem 250 may be utilized either alone or in combination with one another when the HV GCIB processing system 200 is configured to produce ionized clusters using carbon-containing gases, oxygen-containing gases, nitrogen-containing gases, inert gases, carrier gases, metal-containing gases, sulfur-containing gases, or hydrogen-containing gases, or any combination of two or more thereof.

During alignment, testing, and/or operation, the first gas composition and/or the second gas composition may be provided to the HV nozzle subassembly 210, and the nozzle element 212 at a high pressure to produce ionized clusters using carbon-containing gases, oxygen-containing gases, nitrogen-containing gases, inert gases, carrier gases, metal-containing gases, sulfur-containing gases, or hydrogen-containing gases, or any combination of two or more thereof. For example, the first gas composition and/or the second gas composition can be introduced into the process space 211 and can be ejected into the substantially lower pressure vacuum in the first interior space 203 inside the HV source chamber 202. When the high-pressure condensable gas from the nozzle element 212 expands into the lower pressure region of the first interior space 203, the gas molecule velocities can approach supersonic speeds and a HV internal cluster beam 214 (gas jet) is created between the nozzle output aperture 213 and the skimmer input aperture 232 of the inner skimmer element 231, and a neutral cluster beam 247 can emanate from the outer skimmer element 233.

The flow elements in components 220, 221, 222, 240, 241, 242, 243, 244, 250, 251, 252, 253, and 254 can be both gas tight and non-reactive with the variety of gases used. For example, a double walled woven stainless steel mesh with a Kapton or Gore-Tex inner membrane to allow for flex without high gas permeation can be used.

In addition, the gas feed subassembly 220, the HV nozzle subassembly 210, the nozzle element 212, the first mounting elements 215, the HV skimmer subassembly 230, or the first mounting structures 235, or any combination thereof can be fabricated using stainless steel material. Alternatively, the gas feed subassembly 220, the HV nozzle subassembly 210, the nozzle element 212, the first mounting elements 215, the HV skimmer subassembly 230, or the first mounting structures 235, or any combination thereof may be fabricated using hardened and/or coated material.

As discussed above, before the HV GCIB processing system 200 is used, the HV skimmer subassembly 230 can be aligned with the nozzle element 212, and cleaned and/or tested. The HV source chamber 202 can be a closed structure that is configured to sustain a low pressure therein. One or more of the walls of the HV source chamber 202 can include a non-reactive metal such as stainless steel or coated aluminum.

After the neutral cluster beam 247 containing super-sonic gas clusters has been formed, the gas clusters are ionized in an ionization subsystem 260. The ionization subsystem 260, also referred to as the ionizer, can include one or more mounting structures 261 that can be coupled to one or more walls in the HV ionization chamber 205 using one or more third mounting structures 259, and one or more third high-voltage (HV) isolation structures 258. Alternatively, the ionization subsystem 260 may be configured and/or mounted differently. In one embodiment, one or more of the third mounting structures 259 can have a ring or cylindrical shape and can have an outside diameter that can vary from about 200 mm to about 2000 mm; the third HV isolation structures 258 can have a ring or cylindrical shape and can have a width that can vary from about 10 mm to about 200 mm. Alternatively, one or more of the third mounting structures 259 and/or one or more of the third (HV) isolation structures 258 may have different shapes.

In some embodiments, one or more high voltage bushing structures 245 can be configured in one or more of the walls in the HV ionization chamber 205, and a plurality of second feed-through elements (ft₂) can be configured in the high voltage bushing structures 245. Alternatively, the high voltage bushing structures 245 and the second vacuum feed-through elements (ft₂) may be configured and/or mounted differently.

The ionization subsystem 260 can include one or more ion-repeller electrodes 262 that can be configured within and/or attached to one or more of the mounting structures 261. For example, the ion-repeller electrodes 262 can be cylindrically shaped and can have an outside diameter that can vary from about 200 mm to about 2000 mm. In some configurations, the multi-output HV power supply 223 can provide an ion-repeller voltage (V_{IR}) to the ion-repeller electrodes 262. Alternatively, a different power supply may be used. For example, one or more of the ion-repeller electrodes 262 can be connected to one or more outputs (d) on the multi-output HV power supply 223 using one or more supply lines and one or more second feed-through elements (ft₂). In addition, the ion-repeller voltage (V_{IR}) can vary from about 0 volts to about +500 volts, and the multi-output HV power supply 223 can be controlled to provide the correct ion-repeller voltage (V_{IR}) when it is required. Alternatively, the ion-repeller voltage (V_{IR}) can vary from about 0 volts to about +5000 volts.

The ionization subsystem 260 can include one or more electron-repeller electrodes 263 that can be configured within and/or attached to one or more of the mounting structures 261. For example, the electron-repeller electrodes 263 can be cylindrically shaped and can have an outside diameter that can vary from about 200 mm to about 2000 mm. In some configurations, the multi-output HV power supply 223 can provide an electron-repeller voltage (V_{ER}) to at least one of the electron-repeller electrodes 263. Alternatively, a different power supply may be used. For example, one or more of the electron-repeller electrodes 263 can be connected to one or more outputs (c) on the multi-output HV power supply 223 using one or more supply lines and one or more second feed-through elements (ft₂). In addition, the electron-repeller voltage (V_{ER}) can vary from about 0 volts to about −1000 volts, and the multi-output HV power supply 223 can be controlled to provide the correct electron-repeller voltage (V_{ER}) when it is required. Alternatively, the electron-repeller voltage (V_{ER}) can vary from about 0 volts to about −10000 volts.

The ionization subsystem 260 can include one or more ionizer structures 264 that can be configured within and/or attached to one or more of the mounting structures 261. For example, the ionizer structures 264 can have a rectangular shape and can have outside dimensions that can vary from about 100 mm to about 500 mm. Alternatively, the ionizer structures 264 may have a cylindrical shape. In some configurations, the multi-output HV power supply 223 can provide an ionizer voltage (V_{Ion}) to at least one of the ionizer structures 264. Alternatively, a different power supply may be used. For example, one or more of the ionizer structures 264 can be connected to one or more outputs (e) on the multi-output HV power supply 223 using one or more supply lines and one or more second feed-through elements (ft₂). In addition, the ionizer voltage (V_{Ion}) can vary from about 0 volts to about 500 volts, and the multi-output HV power supply 223 can be controlled to provide the correct ionizer voltage (V_{Ion}) when it is required. Alternatively, the ionizer voltage (V_{Ion}) can vary from about 0 volts to about 5000 volts.

The ionization subsystem 260 can include one or more filament structures 265, such as incandescent filaments, that can be configured within and/or attached to one or more of the ionizer structures 264. For example, the filament structures 265 can have a rectangular shape. Alternatively, the filament structures 265 may have a cylindrical shape. In some configurations, the multi-output HV power supply 223 can provide a filament voltage (V_{F}) to at least one of the filament structures 265. Alternatively, a different power supply may be used. For example, one or more of the filament structures 265 can be connected to two or more outputs (f) and (g) on the multi-output HV power supply 223 using two or more supply lines and two or more second feed-through elements (ft₂). In addition, the filament voltage (V_{F}) can vary from about 0 volts to about 10 volts, and the multi-output HV power supply 223 can be controlled to provide the correct filament voltage (V_{F}) to heat the filament structures 265. Alternately, the filament voltage (V_{F}) can vary from about 0 volts to about 100 volts.

Still referring to FIG. 2, the ionization subsystem 260 can include one or more electron extraction electrodes 266 that can be configured within and/or attached to one or more of the mounting structures 261. For example, the electron extraction electrodes 266 can be cylindrically shaped and can have an outside diameter that can vary from about 100 mm to about 1000 mm. Alternatively, the electron extraction electrodes 266 may have a rectangular shape. In some configurations, the multi-output HV power supply 223 can provide an electron extraction voltage (V_{E}) to at least one of the electron extraction electrodes 266. Alternatively, a different power supply may be used. For example, one or more of the electron extraction electrodes 266 can be connected to one or more outputs (h) on the multi-output HV power supply 223 using one or more supply lines and one or more second feed-through elements (ft₂). In addition, the electron extraction voltage (V_{E}) can vary from about 0 volts to about 500 volts, and the multi-output HV power supply 223 can be controlled to provide the correct electron extraction voltage (V_{E}) when it is required. Alternatively, the electron extraction voltage (V_{E}) can vary from about 0 volts to about 5000 volts.

The ionization subsystem 260 can include one or more ion acceleration electrodes 267 that can be configured within and/or attached to one or more of the mounting structures 261. For example, the ion acceleration electrodes 267 can have a substantially cylindrical shape and can have an outside diameter that can vary from about 10 mm to about 100 mm. Alternatively, the ion acceleration electrodes 267 may have a rectangular shape. In some configurations, the multi-output HV power supply 223 can provide an ion acceleration voltage (V_{Acc}) to at least one of the ion acceleration electrodes 267. Alternatively, a different power supply may be used. For example, one or more of the ion acceleration electrodes 267 can be connected to one or more outputs (b) on the multi-output HV power supply 223 using one or more supply lines and one or more second feed-through elements (ft₂). In addition, the ion acceleration voltage (V_{Acc}) can vary from about 0 volts to about +1000 volts, and the multi-output HV power supply 223 can be controlled to provide the correct ion acceleration voltage (V_{Acc}) when it is required.

The ionization subsystem 260 can be configured as an electron impact ionizer that produces thermo-electrons from the one or more filament structures 265 and the electron extraction electrode 266 accelerates and directs the electrons causing them to collide with the gas clusters in the neutral cluster beam 247 as the gas clusters pass through the ionization subsystem 260. The electron impact ejects electrons from the gas clusters, causing a portion of the gas clusters to become positively ionized. Some gas clusters may have more than one electron ejected and may become multiply ionized. The multi-output HV power supply 223 can provide a filament voltage V_{F} to heat the ionizer filament 265.

In some embodiments, the ionization subsystem 260 can include one or more first puller electrodes 268 that can be configured within and/or attached to the HV ionization chamber 205. For example, the first puller electrodes 268 can be cylindrically shaped and can have an inside diameter that can vary from about 10 mm to about 100 mm and an outside diameter that can vary from about 200 mm to about 2000 mm. Alternatively, the ion first puller electrodes 268 may include non-cylindrical shapes. In some configurations, the multi-output HV power supply 223 can provide a first puller voltage V_{P1} to at least one of the first puller electrodes 268. Alternatively, a different power supply may be used. For example, one or more of the first puller electrodes 268 can be connected to one or more outputs (i) on the multi-output HV power supply 223 using one or more supply lines and one or more of the second feed-through elements (ft₂). In addition, the first puller voltage V_{P1} can vary from about 0 volts to about −30000 volts, and the multi-output HV power supply 223 can be controlled to provide the correct first puller voltage V_{P1} when it is required. Alternatively, the first puller voltage V_{P1} can vary from about 0 volts to about −100000 volts.

Furthermore, the ionization subsystem 260 can include one or more second puller electrodes 269 that can be configured within and/or attached to the HV ionization chamber 205. For example, the second puller electrodes 269 can be cylindrically shaped and can have an inside diameter that can vary from about 10 mm to about 100 mm and an outside diameter that can vary from about 200 mm to about 2000 mm. Alternatively, the second puller electrodes 269 may include non-cylindrical shapes. In some configurations, the multi-output HV power supply 223 can provide a second puller voltage V_{P2} to at least one of the second puller electrodes 269. Alternatively, a different power supply may be used. For example, one or more of the second puller electrodes 269 can be connected to one or more outputs (j) on the multi-output HV power supply 223 using one or more supply lines and one or more of the second feed-through elements (ft₂). In addition, the second puller voltage V_{P2} can vary from about 0 volts to about −30000 volts, and the multi-output HV power supply 223 can be controlled to provide the correct second puller voltage V_{P2} when it is required. Alternatively, the second puller voltage V_{P2} can vary from about 0 volts to about −100000 volts.

The one or more first puller electrodes 268 can be used to extract the gas cluster ions from the ionization subsystem 260, forming a beam, and then can be used to accelerate them to a desired energy (typically with acceleration potentials of from several hundred V to several tens of kV) and focus them to form a focused GCIB 249.

In addition, one or more suppressor electrodes 270, 271 can be configured within and/or attached to the HV ionization chamber 205. The suppressor electrodes 270, 271 can be used to extract ions from the ionization subsystem 260, to prevent undesired electrons from entering the ionization subsystem 260 from downstream, and to help form the focused GCIB 249. One or more of the suppressor electrodes 270 can be connected to one or more of the outputs (k) on the multi-output HV power supply 223 using one or more of the third feed-through elements (ft₃), and the multi-output HV power supply 223 can be controlled to provide the correct suppression voltage (V_{S}). For example, the suppression voltage (V_{S}) can vary from about −80000 volts to about 0 volts. Alternatively, the number of suppressor electrodes 270, 271 may be different and the suppression voltage (V_{S}) may be provided differently. Alternatively, the suppression voltage (V_{S}) can vary from about −100000 volts to about 0 volts. In addition, one or more of the suppressor electrodes 271 can be connected to ground potential using one or more of the third feed-through elements (ft₃).

The HV GCIB processing system 200 can include an X-scan controller 282 that provides linear motion of a scanable workpiece holder 280 in the direction of the X-scan motion 283 (into and out of the plane of the paper). A Y-scan controller 284 provides linear motion of the scanable workpiece holder 280 in the direction of Y-scan motion 285, which is typically orthogonal to the X-scan motion 283. During some GCIB processing procedures, the combination of X-scanning and Y-scanning motions can move the workpiece 281, held by the scanable workpiece holder 280, in a raster-like scanning motion through the focused GCIB 249. When the HV GCIB processing system 200 is operating correctly, the focused GCIB 249 can provide a uniform irradiation of a surface of the workpiece 281 thereby causing a uniform processing of the workpiece 281.

During some GCIB procedures, the scanable workpiece holder 280 can position the workpiece 281 at an angle with respect to the axis of the focused GCIB 249 so that the focused GCIB 249 has a beam incidence angle 286 with respect to the surface of the workpiece 281. When the HV GCIB processing system 200 is operating correctly, the beam incidence angle 286 may be about 90 degrees. During Y-scanning, the workpiece 281 can be held by scanable workpiece holder 280 and can be moved from the position shown to the alternate position “A” indicated by the designators 281 A and 280A respectively. When a GCIB processing procedure is performed correctly, the workpiece 281 can be completely scanned through the focused GCIB 249, and in the two extreme positions, the workpiece 281 can be moved completely out of the path of the focused GCIB 249 (over-scanned). In addition, similar scanning and/or over-scanning can be performed in the orthogonal X-scan direction (in and out of the plane of the paper). During some cases, the scanable workpiece holder 280 can be adjusted and/or re-aligned when a scanning procedure failure occurs.

The workpiece 281 can be affixed to the scanable workpiece holder 280 using a clamping system (not shown), such as a mechanical clamping system or an electrical clamping system (e.g., an electrostatic clamping system). Furthermore, the scanable workpiece holder 280 may include temperature control elements (not shown) that may be configured to adjust and/or control the temperature of scanable workpiece holder 280 and workpiece 281.

A beam current sensor 288 can be positioned beyond the scanable workpiece holder 280 in the path of the focused GCIB 249 and can be used to intercept a sample of the focused GCIB 249 when the scanable workpiece holder 280 is scanned out of the path of the focused GCIB 249. The beam current sensor 288 can be a faraday cup or the like, and can be closed except for a beam-entry opening, and can be attached to a wall of the grounded GCIB processing chamber 208 using an electrically insulating mount 289. Alternatively, one or more sensing devices may be coupled to the scanable workpiece holder 280.

The focused GCIB 249 can strike the workpiece 281 at a projected impact region on a surface of the workpiece 281. During X-Y scanning, the scanable workpiece holders 280 can position each portion of a surface of the workpiece 281 in the path of focused GCIB 249 so that every region of the surface of the workpiece 281 can be processed by the focused GCIB 249. The X-Y scan controllers (282, 284) can be used to control the position and velocity of the scanable workpiece holder 280 in the X-axis and the Y-axis directions. The X-Y scan controllers (282, 284) can receive control signals from controller 290 through signal bus 291. During various GCIB processing steps, the scanable workpiece holder 280 can be moved in a continuous motion or in a stepwise motion to position different regions of the workpiece 281 within the focused GCIB 249. In one embodiment, the scanable workpiece holder 280 can be controlled by the controller 290 to scan, with programmable velocity, any portion of the workpiece 281 through the focused GCIB 249.

In some examples, one or more surfaces of the scanable workpiece holder 280 can be constructed to be electrically conductive and can be connected to a dosimetry processor operated by controller 290. An electrically insulating layer (not shown) of scanable workpiece holder 280 may be used to isolate the workpiece 281 and substrate holding surface from the other portions of the scanable workpiece holder 280. Electrical charge induced in the workpiece 281 by impinging the focused GCIB 249 may be conducted through the substrate and substrate holding surface, and a signal can be coupled through the scanable workpiece holder 280 to controller 290 for dosimetry measurement. Dosimetry measurement has integrating means for integrating the GCIB current to determine a GCIB processing dose. Under certain circumstances, a target-neutralizing source (not shown) of electrons, sometimes referred to as electron flood, may be used to neutralize the focused GCIB 249. In such case, a Faraday cup may be used to assure accurate dosimetry despite the added source of electrical charge. During processing of the workpiece 281, the dose rate can be communicated to the controller 290, and the controller 290 can confirm that the GCIB beam flux is correct or to detect variations in the GCIB beam flux.

A controller 290, which may be a microcomputer based controller can be connected to the X-scan controller 282 and the Y-scan controller 284 through signal bus 291 and controls the X-scan controller 282 and the Y-scan controller 284 so as to place the workpiece 281 into or out of the focused GCIB 249 and to scan the workpiece 281 uniformly relative to the focused GCIB 249 to achieve uniform processing of the workpiece 281 by the focused GCIB 249. Controller 290 can receive the sampled beam current collected by the beam current sensor 288 via signal bus 291. The controller 290 can monitor the position of the focused GCIB 249, can control the GCIB dose received by the workpiece 281, and can remove the workpiece 281 from the focused GCIB 249 when a predetermined desired dose has been delivered to the workpiece 281. Alternatively, an internal controller may be used.

The HV GCIB processing apparatus as shown in FIG. 2 includes mechanisms permitting increased GCIB currents while reducing or minimizing “glitches.” The ionizer entrance aperture 267a diameter can vary from about 2 cm to about 4 cm. The length of the ion acceleration electrode 267 can vary from about 2 cm to about 8 cm. The walls of ion acceleration electrode 267 are electrically conductive, preferably metallic, and may be perforated or configured as a plurality of connected, coaxial rings or made of screen material to improve gas conductance.

The HV GCIB processing system 200 may further include an in-situ metrology system. For example, the in-situ metrology system may include an optical diagnostic system having an optical transmitter 272 and optical receiver 275 configured to illuminate the workpiece 281 with an incident optical signal 273 and to receive a scattered optical signal 276 from the workpiece 281, respectively. The optical diagnostic system can include optical windows to permit the passage of the incident optical signal 273 and the scattered optical signal 276 into and out of the grounded GCIB processing chamber 208. Furthermore, the optical transmitter 272 and the optical receiver 275 may comprise transmitting and receiving optics, respectively. The optical transmitter 272 can be coupled to and communicate with the controller 290. The optical receiver 275 returns measurement signals to the controller 290. For example, the in-situ metrology system may be configured to monitor the progress of the GCIB processing.

Controller 290 comprises one or more microprocessors, memory, and I/O ports capable of generating control voltages sufficient to communicate and activate inputs to the HV GCIB processing system 200 as well as monitor outputs from the HV GCIB processing system 200. For example, a program stored in the memory can be utilized to activate the inputs to the aforementioned components of the HV GCIB processing system 200 according to a process recipe in order to perform a GCIB process on a workpiece 281.

In some embodiments, a beam filter 295 can be positioned in the HV ionization chamber 205 and can be used to eliminate monomers or monomers and light ionized clusters from the focused GCIB 249 to further define the focused GCIB 249 before it enters the grounded GCIB processing chamber 208 during GCIB processing. In addition, a beam gate 296 can be disposed in the path of focused GCIB 249 in the HV ionization chamber 205. For example, the beam gate 296 can have an open state in which the focused GCIB 249 is permitted to pass from the HV ionization chamber 205 to the isolated GCIB processing system 207 and a closed state in which the focused GCIB 249 is blocked from entering the isolated GCIB processing system 207. The controller 290 can be coupled to the beam filter 295 and the beam gate 296, and the controller 290 can monitor and control the beam filter 295 and the beam gate 296 during GCIB processing.

Alternatively, an adjustable aperture may be incorporated with the beam filter 295 or included as a separate device (not shown), to throttle or variably block a portion of a GCIB flux thereby reducing the GCIB beam current to a desired value. The adjustable aperture may be employed alone or with other devices and methods known to one skilled in the art to reduce the GCIB flux to a very small value, including by varying the gas flow from a GCIB source supply, or by modulating the ionizer by varying the filament voltage V_{F}.

During some procedures, when an ionized gas cluster ion impinges on a surface of a workpiece 281, a shallow impact crater can be formed with a width of about 20 nm and a depth of about 10 nm, but less than about 25 nm. When imaged using a nano-scale imaging device such as Atomic Force Microscopy (AFM), the impact craters have an appearance similar to indentations. After impact, the inert species from the gas cluster ion vaporizes, or escapes the surface of the workpiece 281 as a gas and can be exhausted from the isolated GCIB processing system 207 by the third vacuum pumping system 225c.

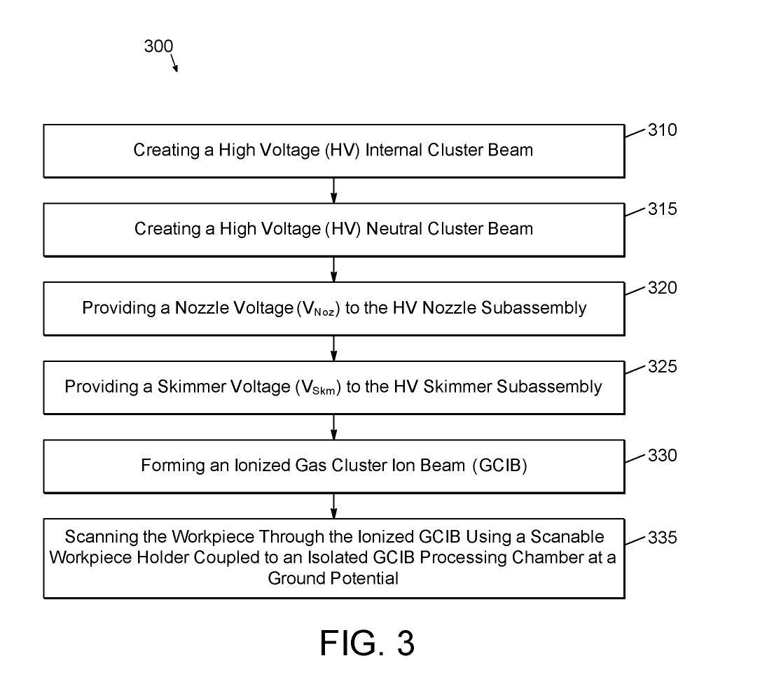

FIG. 3 shows an exemplary flow diagram of a method for treating a workpiece using a high-voltage gas cluster ion beam (HV GCIB) processing system in accordance with embodiments of the invention. The illustrated procedure 300 includes a number of steps, but this is not required for the invention. Alternatively, the number of steps may be different and the procedure 300 may be configured differently.

In 310, an internal cluster beam 214 can be created in the HV source chamber 202 using nozzle element 212 in HV nozzle subassembly 210, and the nozzle element 212 can have a nozzle output aperture 213 that is configured to create the internal cluster beam 214.

In 315, a neutral cluster beam 247 can be created in the HV ionization chamber 205 using HV skimmer subassembly 230, and the HV skimmer subassembly 230 can have a skimmer input aperture 232 and a circular output aperture 234 that can be configured to receive the internal cluster beam 214 and to create the neutral cluster beam 247 in the HV ionization chamber 205.

In 320, a nozzle voltage (V_{Noz}) can be provided to the HV nozzle subassembly 210 using an output from the multi-output HV power supply 223 and the one or more first HV feed-through elements (ft₁).

In 325, a skimmer voltage (V_{Skm}) can be provided to the HV skimmer subassembly 230 using an output from the multi-output HV power supply 223 and the one or more first HV feed-through elements (ft₁).

During various operating procedures, the nozzle voltage (V_{Noz}) can vary within the operating voltages described herein; the skimmer voltage (V_{Skm}) can vary within the operating voltages described herein; the acceleration voltage (V_{Acc}) can vary within the operating voltages described herein; the ion-repeller voltage (V_{IR}) can vary within the operating voltages described herein; the electron-repeller voltage (V_{ER}) can vary within the operating voltages described herein; the electron extraction voltage (V_{E}) can vary within the operating voltages described herein; the filament voltage (V_{F}) can vary within the operating voltages described herein; the first puller voltage (V_{P1}) can vary within the operating voltages described herein; the second puller voltage (V_{P2}) can vary within the operating voltages described herein; and the suppression voltage (V_{S}) can vary within the operating voltages described herein.

In addition, the controller 290 can be coupled to multi-output HV power supply 223 and can be used to control the nozzle voltage (V_{Noz}), the skimmer voltage (V_{Skm}), the acceleration voltage (V_{Acc}), the ion-repeller voltage (V_{IR}), the electron-repeller voltage (V_{ER}), the electron extraction voltage (V_{E}), the filament voltage (V_{F}), the first puller voltage (V_{P1}), second puller voltage (V_{P2}), and the suppression voltage (V_{S}).

In 330, an ionized GCIB 248 can be formed using the ionization subsystem 260 in HV ionization chamber 205 that is coupled to the HV source chamber 202. For example, the ionization subsystem 260 is configured to receive and ionize clusters in the neutral cluster beam 247 to form the ionized GCIB 248. Further, the ionization subsystem can be coupled to the HV ionization chamber 205 using the one or more first isolation structures 258.

In 335, the workpiece 281 can be scanned through the ionized GCIB 248 using scanable workpiece holder 280 that can be coupled to grounded GCIB processing chamber 208, which can be at ground potential. For example, the grounded GCIB processing chamber 208 can be coupled to the HV ionization chamber 205 using the one or more second isolation structures 206a. In addition, the scanable workpiece holder 280 can be configured to establish relative scanning motion between the workpiece 281 and the ionized GCIB 248 so that ionized clusters of the ionized GCIB 248 impinge a surface of the workpiece 281.

Apparatus and method for configuring and using a high-voltage GCIB processing system are disclosed in various embodiments. However, one skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

Various operations will be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

The foregoing description of the embodiments of the invention has been presented for the purposes of illustration and description. It is not intended to be exhaustive or to limit the invention to the precise forms disclosed. This description and the claims following include terms, such as left, right, top, bottom, over, under, upper, lower, first, second, etc. that are used for descriptive purposes only and are not to be construed as limiting. For example, terms designating relative vertical position refer to a situation where a device side (or active surface) of a substrate or integrated circuit is the “top” surface of that substrate; the substrate may actually be in any orientation so that a “top” side of a substrate may be lower than the “bottom” side in a standard terrestrial frame of reference and still fall within the meaning of the term “top.” The term “on” as used herein (including in the claims) does not indicate that a first layer “on” a second layer is directly on and in immediate contact with the second layer unless such is specifically stated; there may be a third layer or other structure between the first layer and the second layer on the first layer. The embodiments of a device or article described herein can be manufactured, used, or shipped in a number of positions and orientations.

Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A high-voltage gas cluster ion beam (GCIB) processing system for treating a workpiece using a gas cluster ion beam (GCIB), the high-voltage GCIB processing system comprising:
a high-voltage (HV) source system including a high-voltage (HV) source chamber having a high-voltage (HV) nozzle subassembly and a high-voltage (HV) skimmer subassembly therein;
a high-voltage (HV) ionization system including a high-voltage (HV) ionization chamber coupled to the HV source chamber;
a nozzle element coupled to the HV nozzle subassembly, wherein the nozzle element has a nozzle output configured to create an internal cluster beam, and the HV skimmer subassembly having an input aperture and an output aperture configured to receive the internal cluster beam and create a neutral cluster beam in the HV ionization chamber;
a multi-output high-voltage (HV) power supply coupled to the HV nozzle subassembly and coupled to the HV skimmer subassembly using one or more first high-voltage (HV) feed-through elements (ft₁);
an ionization subsystem configured within the HV ionization chamber using one or more first high-voltage (HV) isolation structures and coupled to the multi-output HV power supply using one or more second high-voltage (HV) feed-through elements (ft₂), the ionization subsystem being configured to receive and ionize clusters in the neutral cluster beam thereby forming an ionized GCIB;
a scanable workpiece holder coupled to a grounded GCIB processing chamber at a ground potential, the grounded GCIB processing chamber being coupled to the HV ionization chamber using one or more second high-voltage (HV) isolation structures, wherein the scanable workpiece holder is configured for establishing relative scanning motion between the workpiece and the ionized GCIB so that ionized clusters of the ionized GCIB impinge a surface of the workpiece; and
a controller coupled to the multi-output HV power supply and to the scanable workpiece holder using a signal bus.

2. The high-voltage GCIB processing system of claim 1, wherein the nozzle output is separated from a skimmer input aperture by a separation distance (s₁) that varies from about 10 mm to about 100 mm.

3. The high-voltage GCIB processing system of claim 1, wherein the multi-output HV power supply provides a nozzle voltage (V_{Noz}) to the HV nozzle subassembly using the one or more first HV feed-through elements (ft₁), wherein the nozzle voltage (V_{Noz}) varies from about −10,000 volts to about +10,000 volts.

4. The high-voltage GCIB processing system of claim 1, wherein the multi-output HV power supply provides a skimmer voltage (V_{Skm}) to the HV skimmer subassembly using the one or more first HV feed-through elements (ft₁), the skimmer voltage (V_{Skm}) varying from about −10,000 volts to about +10,000 volts.

5. The high-voltage GCIB processing system of claim 1, wherein the ionization subsystem includes one or more first puller electrodes configured within the HV ionization chamber, wherein the multi-output HV power supply provides a first puller voltage (V_{P1}) to the one or more first puller electrodes using the one or more second HV feed-through elements (ft₂), wherein the first puller voltage (V_{P1}) varies from about 0 volts to about −30000 volts.

6. The high-voltage GCIB processing system of claim 5, wherein the ionization subsystem includes one or more second puller electrodes configured within the HV ionization chamber, wherein the multi-output HV power supply provides a second puller voltage (V_{P2}) to the one or more second puller electrodes using the one or more second HV feed-through elements (ft₂), wherein the second puller voltage (V_{P2}) varies from about 0 volts to about −30000 volts.

7. The high-voltage GCIB processing system of claim 1, wherein the ionization subsystem includes one or more suppressor electrodes configured within the HV ionization chamber, wherein the multi-output HV power supply provides a suppression voltage (V_{S}) to the one or more suppressor electrodes using one or more third high-voltage (HV) feed-through elements (ft₃), wherein the suppression voltage (V_{S}) varies from about −80000 volts to about 0 volts.

8. The high-voltage GCIB processing system of claim 1, further comprising:
a first high-voltage gas supply subsystem coupled to the HV nozzle subassembly using at least one first high-voltage isolator element; and
a second high-voltage gas supply subsystem coupled to the HV nozzle subassembly using at least one second high-voltage isolator element.

9. The high-voltage GCIB processing system of claim 1, wherein the multi-output HV power supply provides an optional voltage (V_{Opt}) to at least one terminal coupled to the HV source chamber, wherein the optional voltage (V_{Opt}) varies from about −10000 volts to about +10000 volts.

10. The high-voltage GCIB processing system of claim 9, further comprising:
a first vacuum pumping system coupled to the HV source chamber using at least one first high-voltage (HV) exhaust isolator; and
a second vacuum pumping system coupled to the HV ionization chamber using at least one second high-voltage (HV) exhaust isolator.

11. The high-voltage GCIB processing system of claim 1, wherein the scanable workpiece holder comprises a first axis scanning means and a second axis scanning means.

12. The high-voltage GCIB processing system of claim 1, further comprising:
one or more third isolation structures coupling the HV nozzle subassembly to the HV source chamber.

13. The high-voltage GCIB processing system of claim 12, further comprising:
one or more fourth isolation structures coupling the HV skimmer subassembly to the HV source chamber.

14. The high-voltage GCIB processing system of claim 1, further comprising:
one or more third isolation structures coupling the HV nozzle subassembly to the HV source chamber, wherein the multi-output HV power supply provides a nozzle voltage (V_{Noz}) to the HV nozzle subassembly using the one or more first HV feed-through elements (ft₁), wherein the nozzle voltage (V_{Noz}) varies from about −10,000 volts to about +10,000 volts; and
one or more fourth isolation structures coupling the HV skimmer subassembly to the HV source chamber, wherein the multi-output HV power supply provides a skimmer voltage (V_{Skm}) to the HV skimmer subassembly using the one or more first HV feed-through elements (ft₁), the skimmer voltage (V_{Skm}) varying from about −10,000 volts to about +10,000 volts.

15. A method for treating a workpiece using a high-voltage gas cluster ion beam (GCIB) processing system, the method comprising:
creating an internal cluster beam in a high-voltage (HV) source chamber using a nozzle element in a high-voltage (HV) nozzle subassembly, wherein the nozzle element has a nozzle output configured to create the internal cluster beam;
creating a neutral cluster beam using a high-voltage (HV) skimmer subassembly having an input aperture and an output aperture configured to receive the internal cluster beam and create the neutral cluster beam in a high-voltage (HV) ionization chamber coupled to the HV source chamber;
providing a nozzle voltage (V_{Noz}) to the HV nozzle subassembly using an output from a multi-output high-voltage (HV) power supply and one or more first high-voltage (HV) feed-through elements (ft₁);
providing a skimmer voltage (V_{Skm}) to the HV skimmer subassembly using the multi-output HV power supply and the one or more first HV feed-through elements (ft₁);
forming an ionized gas cluster ion beam (GCIB) using an ionizer in the HV ionization chamber wherein the ionizer is coupled to at least one wall of the HV ionization chamber using one or more first high-voltage (HV) isolation structures and is coupled to the multi-output HV power supply using one or more second high-voltage (HV) feed-through elements (ft₂), the ionizer being configured to receive and ionize clusters in the neutral cluster beam to form the ionized GCIB; and
scanning the workpiece through the ionized GCIB using a scanable workpiece holder coupled to a grounded GCIB processing chamber at a ground potential, the grounded GCIB processing chamber being coupled to the HV ionization chamber using one or more second high-voltage (HV) isolation structures, wherein the scanable workpiece holder is configured for establishing relative scanning motion between the workpiece and the ionized GCIB so that ionized clusters of the ionized GCIB impinge a surface of the workpiece.

16. The method of claim 15, wherein the nozzle voltage (V_{Noz}) varies from about −10000 volts to about +10000 volts.

17. The method of claim 15, wherein the skimmer voltage (V_{Skm}) varies from about −10000 volts to about +10000 volts.
